(19) United States
(12) Patent Application Publication
(10) Pub. No.: US 2024/0421563 A1
(43) Pub. Date: Dec. 19, 2024

(54) DUMMY LIGHT MODULE COMPRISING DUAL SEMICONDUCTOR OPTICAL AMPLIFIER

(71) Applicant: HUAWEI TECHNOLOGIES CO., LTD., Shenzhen (CN)

(72) Inventors: Romain Brenot, Boulogne Billancourt (FR); Gabriel Charlet, Boulogne Billancourt (FR); Nayla El Dahdah, Boulogne Billancourt (FR); Antonin Gallet, Boulogne Billancourt (FR); Hajar Elfaiki, Boulogne Billancourt (FR)

(21) Appl. No.: 18/814,075

(22) Filed: Aug. 23, 2024

Related U.S. Application Data
(63) Continuation of application No. PCT/EP2022/054472, filed on Feb. 23, 2022.

(51) Int. Cl. H01S 5/40; G02B 27/28

(52) U.S. Cl. CPC H01S 5/4012; G02B 27/283; G02B 27/286; H01S 5/4056; H01S 5/4087

(57) ABSTRACT

A dummy light module includes a dual semiconductor optical amplifier (SOA) light source configured to emit two substantially identical light emissions. The two light emissions include a first light emission and a second light emission, both having a first polarization. The dummy light module further includes a polarization rotator configured to rotate the second light emission to a second polarization, and a polarization beam combiner configured to generate dummy light by combining the first light emission with the first polarization and the second light emission with the second polarization.

### CROSS-REFERENCE TO RELATED APPLICATIONS

This application is a continuation of International Application No. PCT/EP2022/054472, filed on Feb. 23, 2022, the disclosure of which is hereby incorporated by reference in its entirety.

### FIELD

The present disclosure relates generally to dummy light modules; and more specifically to a dummy light module including a dual semiconductor optical amplifier.

### BACKGROUND

Conventionally, wavelength-division multiplexing is a technology which multiplexes a number of optical carrier signals onto a single optical fiber by using different wavelengths of laser light. Furthermore, devices using wavelength-division multiplexing are configured to modulate multiple signals into light of different wavelengths and performs wavelength-division multiplexing on the light of the wavelengths for transmission.

In wavelength-division multiplexing transmission links, modules are required to maintain a stable power of an optical amplifier. Herein, such modules exist for conventional band (C-band) transmission links, using cascaded Erbium-Doped Fiber Amplifier (EDFA), wherein EDFA can amplify multiple optical signals simultaneously, and this can be easily combined with WDM technology. Furthermore, to increase capacity of the optical fiber, a wider optical bandwidth may be used, such as C-band and long band (L-band), or a combination of short-wavelength band (S-band), C-band and L-band. However, the modules often exceed cost, has a high-power consumption and has a large footprint in case the module is operated in any frequency bandwidth.

The EDFA module can be connected in a cascaded manner to ensure an efficient functioning of the module. However, the cascaded EDFA modules are bulky and expensive, and the module might have a same size as laser executing one pump to transfer energy into a gain medium of one EDFA. Furthermore, a reflective semiconductor optical amplifier (RSOA) may be used for a wide optical bandwidth and to procure a high output power covering the C-band and the L-band. However, polarization dependent loss (PDL) control required a particular selection of the RSOA, wherein current tuning may be required, and the PDL may not be less then 0.5 decibel (dB). Typically, the RSOA suffers from spectral ripple, which requires anti-reflection coating of a superior quality. Moreover, the RSOA cannot easily control flatness of gain inside the module.

Therefore, in light of the foregoing discussion, there exists a need to overcome the aforementioned drawbacks associated with the conventional methods of modules using the wavelength-division multiplexing.

### SUMMARY

The present disclosure provides embodiments of a dummy light module. The present disclosure provides a solution to the existing problems of high power consumption, high cost and increase in footprint. Aspects of the present disclosure provides a solution that overcomes at least partially the problems encountered in prior art, and provides an improved dummy light module.

In one aspect, the present disclosure provides a dummy light module. The dummy light module further comprises a dual semiconductor optical amplifier, SOA, light source configured to emit two substantially identical light emissions, where each light emission has a first polarization, a polarization rotator to rotate one of the light emissions to a second polarization, and a polarization beam combiner configured to generate dummy light by combining the light emission with the first polarization and the light emission with the second polarization.

The dummy light module comprises dual SOA that is compact in nature and can operate in a wavelength of choice. Moreover, development of the dummy light module using dual SOA is low in cost, has a lower power consumption, and a small footprint. Furthermore, the dummy light module has potential to replace Erbium-Doped Fiber Amplifier (EDFA) based modules.

In an implementation form, the dual SOA light source comprises one or more SOA units configured to emit light; wherein each SOA unit is configured to emit light in two opposite directions.

This is advantageous since, photons have same wavelength as the two substantially identical light emissions, thus amplifying the two substantially identical light emissions in two opposite directions. Additionally, the first polarization is used to eliminate polarization dependent losses (PDL) of the two substantially identical light emissions.

In an implementation form, the dual SOA light source comprises two SOA units and a first emitting direction of each SOA unit is directed towards a reflector array arranged to redirect the light back to the other SOA unit; and a second emitting direction of the SOA units outputs the two substantially identical light emissions.

This is advantageous since in case the PASE of the front facet and back facet are the emitted ASE in decibel, then the PASE of the front facet is equal to the PASE of the back facet. With respect to the second SOA unit, in case the PASE of the front facet and back facet are the emitted ASE in decibel, then the PASE of the front facet is equal to the PASE of the back facet. Furthermore, when the first SOA unit and the second SOA unit are connected in a loop architecture, then the polarization dependent losses, PDL are subtracted. Additionally, saturation issues are not included.

In an implementation form, wherein a first emitting direction of each SOA unit is directed towards a corresponding reflector arranged to redirect the light back to the SOA unit; and a second emitting direction of each SOA unit is directed towards a power splitter configured to receive the light emitted by each of the SOA units and output the two substantially identical light emissions.

This is advantageous since, the power splitter is well balanced to obtain a low polarization dependent loss (PDL).

In an implementation form, the dual SOA light source comprises at least a first SOA unit configured to emit light in a first band, and a second SOA unit configured to emit light in a second band different to the first band.

This is advantageous since, the ASE flatness between the frequency bands is easily controllable. Moreover, wide frequency band is permitted.

In an implementation form, the dual SOA light source further comprises a first band multiplexer configured to combine each band of light emitted in the first direction and direct the combined light to a common reflector.

This is advantageous since, the first band multiplexer performs multiplexing with free space optical (FSO), silicon nitride (SiN), glass and so forth. Furthermore, the emitted light subsequently passes through the power splitter, and experiences no multiplexing losses.

In an implementation form, the dual SOA light source further comprises a wideband SOA unit arranged between the first band multiplexer and the common reflector, and configured to emit wideband light in two opposite directions, wherein the wideband light includes at least first band and second band.

This is advantageous since, the wideband SOA unit generates the dummy light for both frequency bands. Beneficially, power consumption is lowered. Additionally, high power is achieved when wideband SOA unit is used.

In an implementation form, the dual SOA light source further comprises one or more additional SOA units each configured to emit light in a respective band different from each other band; and a second band multiplexer configured to combine each band of light emitted in the second direction and direct the combined light to the power splitter.

This is advantageous since, the second band multiplexer performs multiplexing with free space optical (FSO), silicon nitride (SiN), glass and so forth. Furthermore, the emitted light subsequently passes through the power splitter, and experiences no multiplexing losses.

In an implementation form, the first emitting direction of each SOA unit is directed to pass through a gain flattening filter (GFF) configured to flatten an emission profile of the dummy light.

This is advantageous since, conversion efficiency is improved over any frequency band if interest, along with flatness of gain of the emitted light. Furthermore, low PDL will be obtained in all cases.

In an implementation form, the GFF is further configured to increase an output power in a frequency band.

This is advantageous since, PASE of each of the SOA units is improved, and value of the GFF is subtracted, thereby improving power spectral density of the dummy light module over the interested band of frequency.

It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, features and objects of the present disclosure would be made apparent from the drawings and the detailed description of the illustrative implementations construed in conjunction with the appended claims that follow.

### BRIEF DESCRIPTION OF THE DRAWINGS

For the purpose of illustrating embodiments of the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will be described, by way of example only, with reference to the following diagrams wherein:

FIG. 1 is a block diagram of a dummy light module comprising a dual semiconductor optimal amplifier (SOA) light source configured to emit two substantially identical light emissions, in accordance with an embodiment of the present disclosure;

FIG. 2A is a block diagram of a dummy light module, wherein a dual SOA light source comprises one or more SOA unit configured to emit light, in accordance with an embodiment of the present disclosure;

FIG. 2B is a block diagram of the dummy light module, wherein the dual SOA light source comprises two SOA units in a loop, in accordance with an embodiment of the present disclosure;

FIG. 3 is a block diagram of a dummy light module, wherein a polarization beam combiner is configured to receive light emitted by each of the SOA units, in accordance with another embodiment of the present disclosure;

FIG. 4A is a block diagram of a dummy light module, wherein the first emitting direction of each SOA unit passes through a gain flattening filter (GFF) in accordance with an implementation of the present disclosure;

FIG. 4B is a graphical representation that illustrates insertion of a GFF in the dummy light module, in accordance with an embodiment of the present disclosure;

FIG. 5A is a block diagram of a dummy light module, wherein the dual SOA light emits light in different frequency bands, in accordance with an embodiment of the present disclosure;

FIG. 5B is a block diagram of a dummy light module, wherein the dual SOA unit comprises a first band multiplexer, in accordance with an embodiment of the present disclosure;

FIG. 6 is a block diagram of a dummy light module, wherein a wideband SOA unit is arranged in the dummy light module, in accordance with an embodiment of the present disclosure;

FIG. 7 is a graphical representation that illustrates a dummy light module without GFF, in accordance with an embodiment of the present disclosure; and

FIG. 8 is a graphical representation that illustrates the dummy light module with the GFF fabricated, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow, the non-underlined number is used to identify a general item at which the arrow is pointing.

### DETAILED DESCRIPTION

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

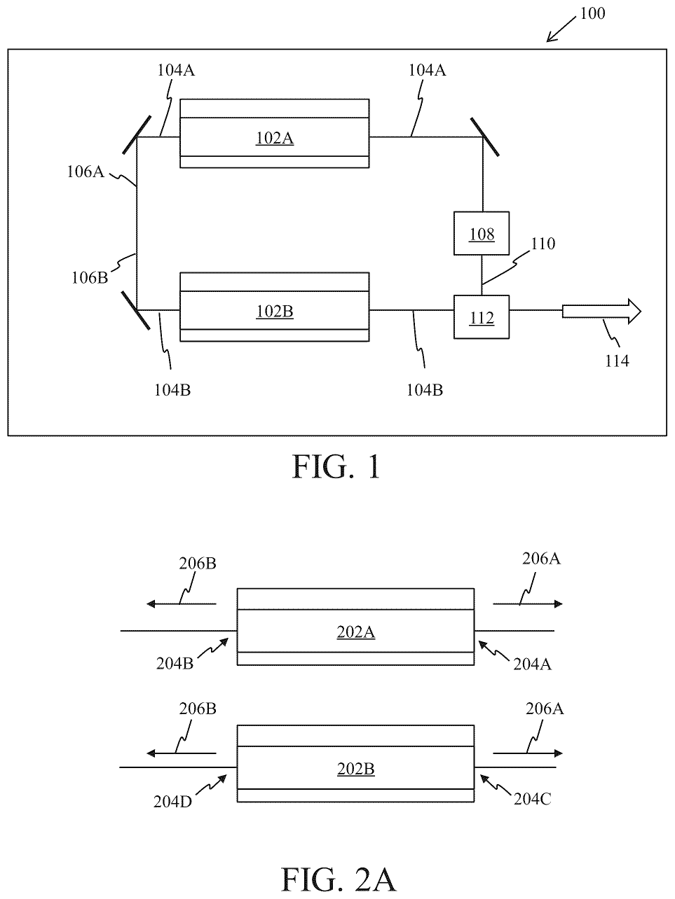

FIG. 1 is a block diagram of a dummy light module comprising a dual semiconductor optimal amplifier (SOA) light source configured to emit two substantially identical light emissions, in accordance with an embodiment of the present disclosure. With reference to FIG. 1, there is shown a dummy light module 100. The dummy light module 100 comprises the dual SOA 102A and 102B light source. Herein, the light emitted from the dual SOA 102A light source acts as a source of light for the dual SOA 102B and vice versa. Herein, the dual SOA 102A and 102B light source are configured to emit two substantially identical light emissions 104A and 104B. Additionally, the two substantially identical light emissions 104A and 104B undergo a first polarization 106A and 106B. Furthermore, the dummy light module 100 comprises a polarization rotator 108 to procure second polarization 110 of the emitted light. The light emissions pass through a polarization rotator 108 to rotate polarization axis of the light emission. Additionally, the dummy light module 100 comprises a polarization beam combiner 112 configured to generate dummy light 114 by combining the light emission with the first polarization 106A, 106B and the light emission with the second polarization 110.

The dummy light module 100 is an electronic device that is required to maintain a stable total input power at input of an optical amplifier. Herein, an optical amplifier is a device that amplifies an optical signal directly, without the need to first convert it to an electrical signal, wherein the optical signal are two substantially identical light emissions 104A and 104B. Furthermore, using the dummy light module 100 enables avoiding unwanted transients in gain.

The dual SOA 102A and 102B light source, is configured to emit two substantially identical light emissions 104A and 104B. Herein, the dual SOA 102A and 102B light source is an optical amplifier based on a semiconductor gain medium that amplifies light. Additionally, the dual SOA 102A and 102B comprises non-reflecting ends and broad wavelength emission. Subsequently, the two substantially identical light emissions 104A and 104B enters from outside the dual SOA 102A and 102B light source, the two substantially identical light emissions 104A and 104B is amplified by stimulated emission. Moreover, when the two substantially identical light emissions 104A and 104B travels through active region of the dual SOA 102A and 102B, it causes electrons in the two substantially identical light emissions 104A and 104B to lose energy in the form of photons and return to a ground state. Typically, the photons have same wavelength as the two substantially identical light emissions 104A and 104B, thus amplifying the two substantially identical light emissions 104A and 104B.

The two substantially identical light emissions 104A and 104B passing through the dual SOA 102A and 102B light source has a first polarization 106A and 106B. Herein, the first polarization 106A and 106B may be a transverse electric (TE) polarization. Additionally, the first polarization is used to eliminate polarization dependent losses (PDL) of the two substantially identical light emissions 104A and 104B.

The dummy light module 100 comprises a polarization rotator 108, to rotate one of the light emissions to a second polarization 110. Herein, the polarization rotator 108 is an optical device that alters polarization state of the first polarization 106A and 106B travelling through the polarization rotator 108 to transverse magnetic (TM) polarized light, wherein the transverse magnetic (TM) polarized light is the second polarization 110. Additionally, the TM polarized light is characterized by a magnetic field being perpendicular to plane of incident. Furthermore, polarization direction of the second polarization 110 shifts after getting rotated from the polarization rotator 108. The polarization rotator 108 comprises a half-wave plate that is constructed out of a birefringent material such as quartz, mica and so forth. Furthermore, the half-wave plate acts as the isolator for suppressing back reflections to avoid feedback issues. Subsequently, the second polarization 110 that passes through the polarization rotator 108 rotates the polarization axis of the light emissions by an angle of choice. Herein, the polarization rotator 108 may be based on Faraday effect, birefringence, or on total internal reflection.

The dummy light module 100 comprises a polarization beam combiner 112 configured to generate dummy light 114 by combining the light emission with the first polarization 106A and 106B and the light emission with the second polarization 110. Herein, the polarization beam combiner 112 combines two orthogonal polarization components into one dummy light 114. Furthermore, a typical configuration of the polarization beam combiner 112 uses two polarization-maintaining (PM) optical fibers for light source, and single-mode (SM) optical fiber for dummy light 114.

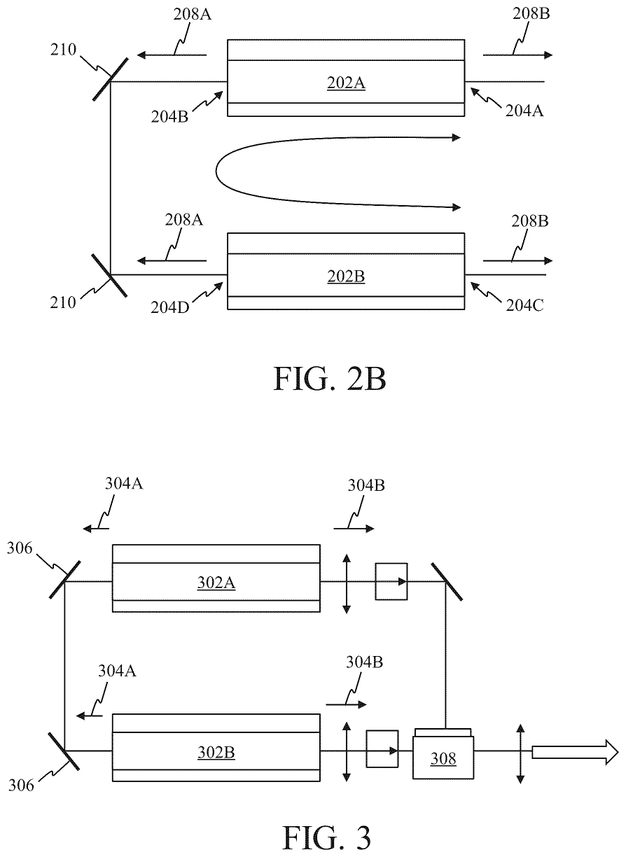

FIG. 2A is a block diagram of a dummy light module, wherein a dual SOA light source comprises one or more SOA units configured to emit light, in accordance with an embodiment of the present disclosure. FIG. 2A is described in conjunction with elements from FIG. 1. With reference to FIG. 2A, there is shown dual SOA light source comprising one or more SOA units, wherein the first SOA unit is 202A and the second SOA unit is 202B. Furthermore, the first SOA unit 202A comprises a front facet 204A and a back facet 204B. Additionally, the second SOA unit 202B comprises a front facet 204C and a back facet 204D. Herein, each of the SOA units 202A and 202B emits light in two opposite directions 206A and 206B.

In accordance with an embodiment, dual SOA 102A and 102B light source comprises one or more SOA units 202A and 202B configured to emit light, wherein each SOA unit 202A and 202B is configured to emit light in two opposite directions from front and back facets of each SOA units 202A and 202B. Herein, power of amplified spontaneous emission, PASE is calculated for the front facet 204A and the back facet 204B of the first SOA unit 202A and the front facet 204C and the back facet 204D of the second SOA unit 202B. Typically, amplified spontaneous emission, ASE is light, produced by spontaneous emission, is optically amplified by process of stimulated emission in a gain medium. With respect to the first SOA unit 202A, in case the PASE of the front facet 204A and back facet 204B are the emitted ASE in decibel, then the PASE of the front facet 204A is equal to the PASE of the back facet 204B. With respect to the second SOA unit 202B, in case the PASE of the front facet 204C and back facet 204D are the emitted ASE in decibel, then the PASE of the front facet 204C is equal to the PASE of the back facet 204D.

FIG. 2B is a block diagram of the dummy light module, wherein the dual SOA light source comprises two SOA units in a loop, in accordance with an embodiment of the present disclosure. FIG. 2B is described in conjunction with elements from FIG. 2A. With reference to FIG. 2B, there is shown the first SOA unit 202A and the second SOA unit 202B. Herein, the first SOA unit 202A and a second SOA unit 202B is arranged in a loop architecture. The first SOA unit 202A comprises the front facet 204A and the back facet 204B, and the second SOA unit 202B comprises a front facet 204C and a back facet 204D. The first emitting direction 208A of the first SOA unit 202A and the second SOA unit 202B is directed towards a reflector array 210. Furthermore, the second emitting direction 208B of the first SOA unit 202A and the second SOA unit 202B outputs the two substantially identical light emissions.

In accordance with an embodiment, the dual SOA light source comprises two SOA units, namely the first SOA unit 202A and the second SOA unit 202B. Herein, the first emitting direction 208A of the first SOA unit 202A and the second SOA unit 202B is directed towards a reflector array 210 arranged to redirect the light back to the other SOA unit. Furthermore, the second emitting direction 208B of the first SOA unit 202A and the second SOA unit 202B outputs the two substantially identical light emissions. Notably, the first SOA unit 202A and the second SOA unit 202B is arranged in a loop architecture, wherein the PASE of the front facet 204A of the first SOA unit 202A and the front facet 204C of the second SOA unit 202B increases by the PASE of the back facet 204B of the first SOA unit 202A and the back facet 204D of the second SOA unit 202B. Furthermore, gain is added to the PASE of the back facet 204B of the first SOA unit 202A and the back facet 204D of the second SOA unit 202B, and losses due to the loop architecture are subtracted. Herein, the losses are difference between PASE of the back facet 204B of the first SOA unit 202A and the back facet 204D of the second SOA unit 202B and the PASE of the back facet 204D of either the second SOA unit 202B or the back facet 204B the first SOA unit 202A. Moreover, saturation issues are not included during calculation, hence the PASE values of the first SOA unit 202A and the second SOA unit 202B are valid until emitted PASE approaches saturation output power of the dual SOA light source.

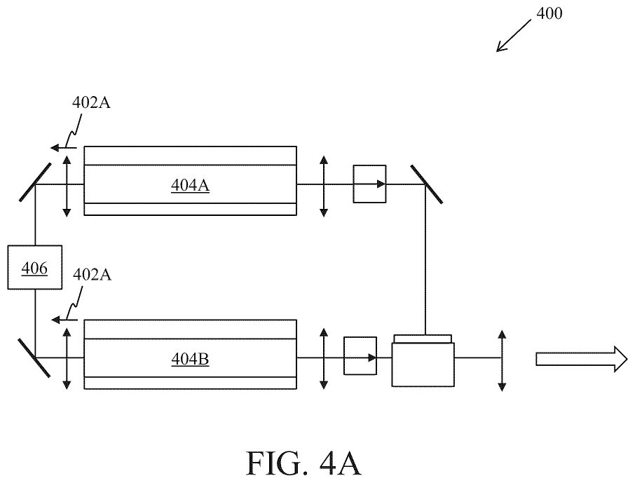

FIG. 3 is a block diagram of a dummy light module, wherein a polarization beam combiner is configured to receive light emitted by each of the SOA units, in accordance with an embodiment of the present disclosure. FIG. 3 is described in conjunction with elements from FIG. 1. With reference to FIG. 3, there is shown a dummy light module 300 comprising a first SOA unit 302A and a second SOA unit 302B. Furthermore, a first emitting direction 304A of the first SOA unit 302A and a second SOA unit 302B is directed towards a corresponding reflector 306. The second emitting direction 304B of the first SOA unit 302A and a second SOA unit 302B is directed towards the polarization beam combiner 308.

In accordance with an embodiment of the present disclosure, the first emitting direction 304A of the first SOA unit 302A and a second SOA unit 302B is directed towards a corresponding reflector 306, wherein the reflector 306 is arranged to redirect the light back to the first SOA unit 302A and a second SOA unit 302B. Additionally, the second emitting direction 304B of the first SOA unit 302A and a second SOA unit 302B is directed towards the power splitter 308, wherein the polarization beam combiner 308 is configured to receive the light emitted by each of the SOA units, i.e., the first SOA unit 302A and a second SOA unit 302B and output the two substantially identical light emissions. Herein, the polarization beam splitter, PBS as the polarization beam combiner 308 is used to combine the polarized light emitted by each of the SOA units, i.e., the first SOA unit 302A and a second SOA unit 302B. Furthermore, the polarization beam combiner 308 is well balanced to obtain a low polarization dependent loss, PDL. Herein, PDL is a measure of peak-to-peak difference of the dummy light module 300 with respect to all possible states of polarization.

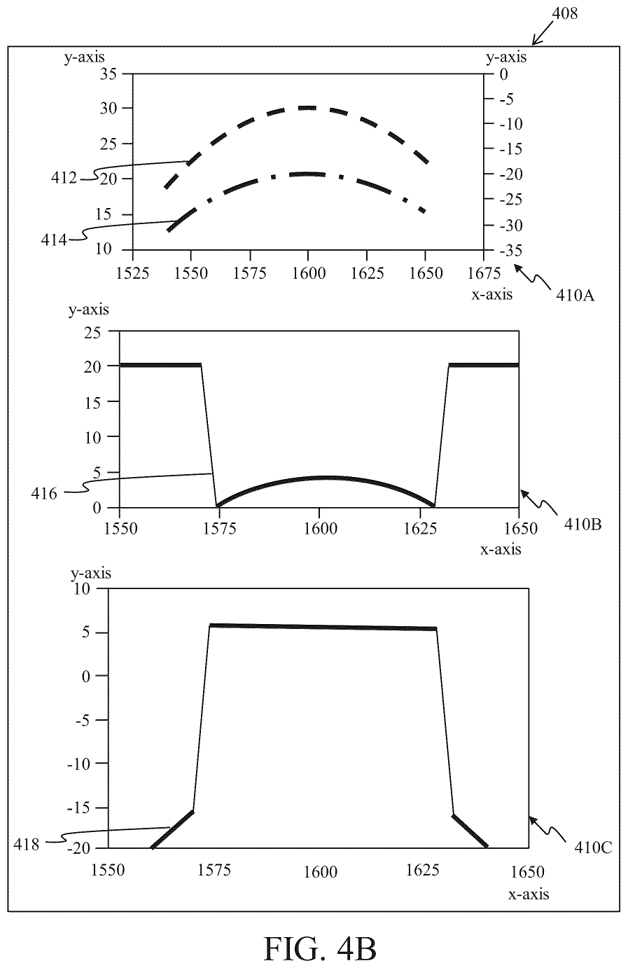

FIG. 4A is a block diagram of a dummy light module, wherein the first emitting direction of each SOA unit passes through a gain flattening filter (GFF) in accordance with an embodiment of the present disclosure. Herein, the dummy light module 400 comprises the first emitting direction 402A of each SOA unit, namely a first SOA unit 404A and a second SOA unit 404B, passes through a gain flattening filter (GFF) 406.

In accordance with an embodiment, the first emitting direction 402A of each SOA unit, namely a first SOA unit 404A and a second SOA unit 404B is directed to pass through the GFF 406, wherein the GFF 406 is configured flatten an emission profile of the dummy light. Herein, the GFF 406 is used to flatten or smoothen out unequal light emissions from the first SOA unit 404A and the second SOA unit 404B over a specified wavelength range. Furthermore, the GFF 406 is inserted in center of the loop architecture of the dummy light module 400, to improve conversion efficiency over any frequency band of interest, along with flatness of gain of the emitted light. Herein, the frequency band may be any part or combination of telecommunication bands, from 1260 nm to 1650 nm, or in other wavelength ranges. Herein, the dummy light module 400 may be operated either by switching on either the first SOA unit 404A or the second SOA unit 404B, wherein either one of the first SOA unit 404A or the second SOA unit 404B may be used in case the other one encounters a failure, or both the first SOA unit 404A or the second SOA unit 404B simultaneously, thereby delivering 3 dB more power. Hence, low PDL will be obtained in all cases.

FIG. 4B is a graphical representation that illustrates insertion of a GFF in the dummy light module, in accordance with an embodiment of the present disclosure. FIG. 4B is described in conjunction with elements from FIG. 4A. With reference to FIG. 4B, there is shown a graphical representation 408 that comprises graphs 410A, 410B and 410C. With reference to graph 410A, there is shown a relationship amongst gain and PASE for each SOA unit alone with respect to wavelength. With reference to graph 410B, there is shown a filter for a frequency band, for instance, the L-band. With reference to graph 410C, there is shown PASE for each of the SOA units in a loop architecture, wherein the graph 410C is the output of the combination of graphs 410A and 410B. Additionally, the x-axis of the graph 410A represents gain in decibels (dB) and ASE in decibel milliwatts per nanometer (dBm/nm) and the y-axis represents wavelength in nanometer (nm). Furthermore, the x-axis of the graph 410B represents filter losses in dB and the y-axis represents wavelength in nanometer (nm). Moreover, the x-axis of the graph 410A represents ASE in dBm/nm and the y-axis represents wavelength in nanometer (nm).

In the graph 410A of the graphical representation 408, the lines 412 and 414 illustrates the gain in decibels (dB) and the ASE in decibel milliwatts per nanometer (dBm/nm) of the first SOA unit 404A and the second SOA unit 404B respectively, with respect to the wavelength in nanometers (nm). In the graph 410B of the graphical representation 408, the line 416 illustrates filter losses after insertion of GFF in the L-band. The graphs 410A and 410B are used to procure the graph 410C. In the graph 410C of the graphical representation 408, the line 418 illustrates PASE when the first SOA unit 404A and the second SOA unit 404B are in loop architecture.

In accordance with an embodiment, the GFF 406 is further configured to increase an output power in the frequency band. Herein, the frequency band may be a long band, L-band, a conventional band, C-band, a satellite communications band, S-band, a combination of the S-band and the C-band, the combination of C-band and L-band, or the combination of S-band, C-band and L-band, and may also cover other frequency bands such as X-band, K-band, V-band and so forth. Moreover, to improve PASE of the front facet of each of the SOA units, namely the first SOA unit 404A and the second SOA unit 404B. Subsequently, value of the GFF 406 is subtracted from the previously calculated PASE value of the front facet of the SOA unit 404A and the second SOA unit 404B, thereby improving power spectral density of the dummy light module 400 over the interested band of frequency.

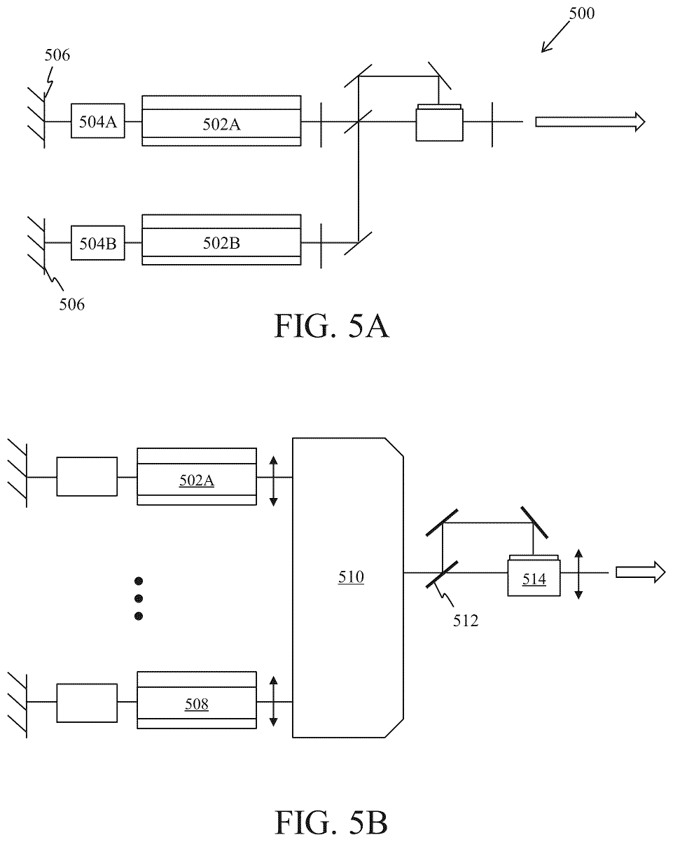

FIG. 5A is a block diagram of a dummy light module, wherein the dual SOA light emits light in different frequency bands, in accordance with an embodiment of the present disclosure. Herein, the dummy light module 500 comprises a first SOA unit 502A emitting light in a first frequency band and a second SOA unit 502B emitting light in a second frequency band. The first SOA unit 502A and the second SOA unit 502B are operably coupled to a first GFF 504A and a second GFF 504B. Subsequently, the first GFF 504A and the second GFF 504B is coupled to a back mirror 506.

In accordance with an embodiment, the dual SOA light source comprises at least a first SOA unit 502A configured to emit light in a first band. Notably, the second SOA unit 502B configured to emit light in a second band, wherein the second band is different to the first band. Herein, the first band and the second band may be the L-band, the C-band, the S-band, the combination of S-band and C-band, the combination of C-band and L-band. Furthermore, the emitted light from the first SOA unit 502A passes through the first GFF 504A to flatten or smoothen out unequal light emissions. Additionally, the emitted light from the second SOA unit 502B passes through the second GFF 504B to flatten or smoothen out unequal light emissions. Herein, the ASE flatness between the frequency bands can be more easily controlled. Furthermore, the first GFF 504A and the second GFF 504B ensures conversion efficiency and flatness of the ASE spectrum. Subsequently, the first GFF 504A and the second GFF 504B is coupled to a back mirror 506. Hence, the back mirror coupled with the first SOA unit 502A and the second SOA unit 502B is configured as a reflective SOA (RSOA) unit. Consequently, dummy lights that are unpolarized and comprising wide frequency band is emitted.

FIG. 5B is a block diagram of a dummy light module, wherein the dual SOA unit comprises a first band multiplexer, in accordance with an embodiment of the present disclosure. FIG. 5B is described in conjunction with elements from FIG. 5A. With reference to FIG. 5B, there is shown a dual SOA light source comprising the first SOA unit 502A and an n-th SOA unit 508 operably coupled to a first band multiplexer 510, wherein “n” denotes an integer. A combination of each band of light emitted from the first band multiplexer 510 and is directed to a common reflector 512. The emitted light from the first band multiplexer 510 passes through the power splitter 514.

In accordance with an embodiment, the dual SOA light source comprises a first band multiplexer 508, wherein the first band multiplexer 510 is configured to combine each band of light emitted in the first direction and direct the combined light to a common reflector 512. Herein, the first band multiplexer 510 may perform multiplexing with free space optical (FSO), silicon nitride (SiN) three mode division multiplexing, glass and so forth. Consequently, the emitted light from the first band multiplexer 510 passes through the power splitter 514, and experiences no multiplexing losses. Additionally, the dummy lights that are unpolarized and comprising wide frequency band is emitted.

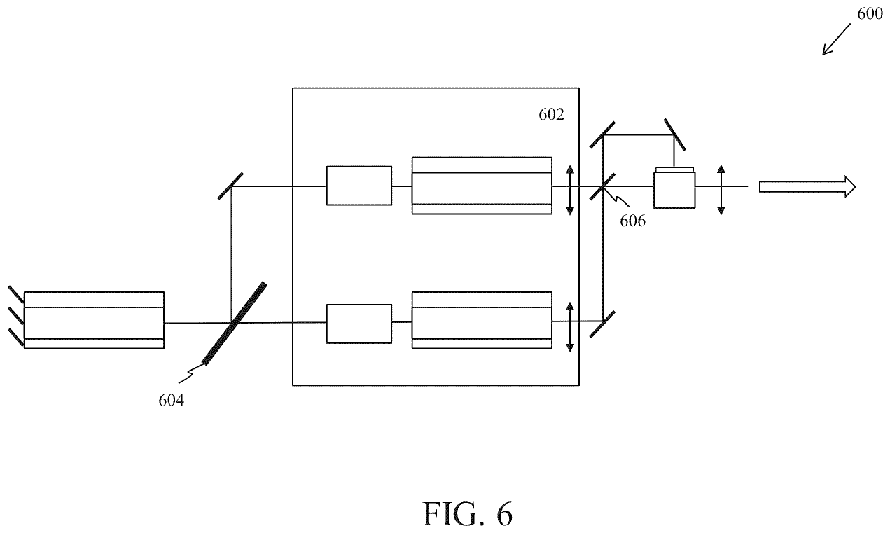

FIG. 6 is a block diagram of a dummy light module, wherein a wideband SOA unit is arranged in the dummy light module, in accordance with an embodiment of the present disclosure. Herein, the dummy light module 600 comprises a dual SOA light source. The dual SOA source further comprises a wideband SOA unit 602 arranged between the first band multiplexer 604 and the common reflector 606.

In accordance with an embodiment, the dummy light module 600 comprises the dual SOA light source, which further comprises the wideband SOA unit 602 arranged between the first band multiplexer 604 and the common reflector 606, and configured to emit wideband light in two opposite directions, wherein the wideband light includes at least first band and second band. Herein, the wideband SOA unit 602 is the RSOA to generate the dummy light for both frequency bands. Furthermore, the benefit is to use a wideband SOA unit 602 is to lower power consumption. Additionally, high power will be achieved with the wideband SOA unit 602, wherein the wideband SOA unit 602 amplifies in each frequency band. Moreover, the wideband SOA unit 602 emits wideband ASE with moderate power consumption.

In accordance with an embodiment, the dual SOA light source further comprises one or more additional SOA units each configured to emit light in a respective band different from each other band. Furthermore, a second band multiplexer is configured to combine each band of light emitted in the second direction and direct the combined light to the power splitter. Herein, the second band multiplexer may perform multiplexing with free space optical (FSO), silicon nitride (SiN) three mode division multiplexing, glass and so forth. Consequently, the emitted light from the second band multiplexer passes through the power splitter, and experiences no multiplexing losses.

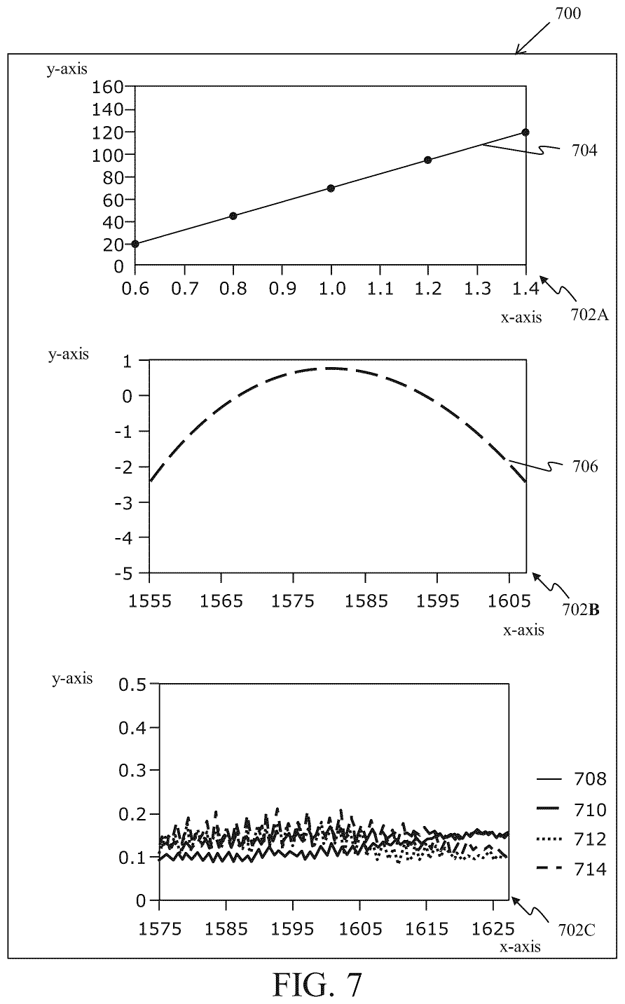

FIG. 7 is a graphical representation that illustrates a dummy light module without GFF, in accordance with an embodiment of the present disclosure. With reference to FIG. 7, there is shown a graphical representation 700 that comprises graphs 702A, 702B and 702C. With reference to graph 702A, there is shown total PASE at 20 degrees Celsius. With reference to graph 702B, there is shown a relationship between power spectrum and wavelength. With reference to graph 702C, there is shown a relationship between PDL with respect to wavelength. Additionally, the x-axis of the graph 702A represents bias current in ampere (A) and the y-axis represents power in milliwatts (mW). Furthermore, the x-axis of the graph 702B represents power spectrum in decibel milliwatts per nanometer (dBm/nm) and the y-axis represents wavelength in nm. Moreover, the x-axis of the graph 702C represents PDL in decibel per one-tenth nanometer (dB/0.1 nm) and the y-axis represents wavelength in nm.

In the graph 702A of the graphical representation 700, the line 704 illustrates the total PASE in mW at 20 degrees Celsius, wherein the total PASE greater than 20 mW is achieved with the increase in bias current. In the graph 702B of the graphical representation 700, the line 706 illustrates power spectrum as output, wherein the line 706 has a bandwidth of 52 nm and 3 dB. In the graph 702C of the graphical representation 700, the lines 708, 710, 712 and 714 illustrate PDL for various values of bias currents. In particular, the line 708 illustrates PDL of a given wavelength for a particular bias current, that may be for example ‘0.6’, the line 710 illustrates PDL of a given wavelength for a particular bias current, that may be for example ‘0.8’, the line 712 illustrates PDL of a given wavelength for a particular bias current, that may be for example ‘1’, the line 714 illustrates PDL of a given wavelength for a particular bias current, that may be for example ‘1.2’. Furthermore, PDL of less than 0.2 dB is achieved for all the wavelengths and the various bias currents.

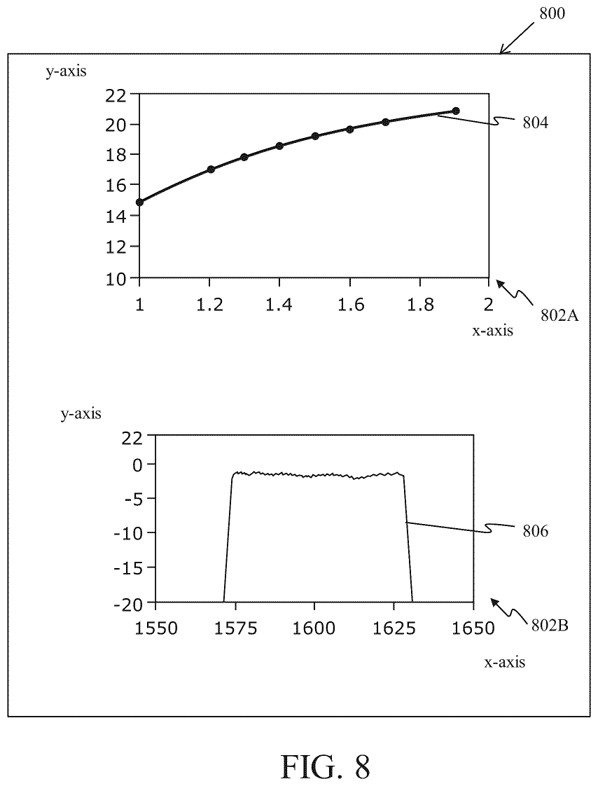

FIG. 8 is a graphical representation that illustrates the dummy light module with the GFF fabricated, in accordance with an embodiment of the present disclosure. With reference to FIG. 8, there is shown a graphical representation 800 that comprises graphs 802A and 802B. With reference to graph 802A, there is shown a relationship between total PASE in L-band with respect to current in ampere (A). With reference to graph 802B, there is shown a relationship between spectrum density with relationship to wavelength. Additionally, the x-axis of the graph 802A represents total PASE in L-band in decibel milliwatts (dBm) and the y-axis represents current in ampere (A). Furthermore, the x-axis of the graph 802B represents spectrum density in decibel milliwatts per 50 gigahertz frequencies (dBm/50 GHz).

In the graph 802A of the graphical representation 800, the line 804 illustrates the total PASE in L-band, wherein the total PASE in L-band greater than 20 dBm is achieved. In the graph 802B of the graphical representation 800, the line 806 represents target specification of the spectrum density.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments and/or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the present disclosure, which are, for brevity, described in the context of a single embodiment, may also be provided separately or in any suitable combination or as suitable in any other described embodiment of the disclosure.

What is claimed is:

1. A dummy light module, comprising:
a dual semiconductor optical amplifier (SOA) light source configured to emit two light emissions, wherein the two light emissions include a first light emission and a second light emission both having a first polarization;
a polarization rotator configured to rotate the second light emission to a second polarization; and
a polarization beam combiner configured to generate dummy light by combining the first light emission with the first polarization and the second light emission with the second polarization.

2. The dummy light module of claim 1, wherein the dual SOA light source comprises one or more SOA units, wherein each SOA unit is configured to emit light in a first emitting direction and a second emitting direction opposite the first emitting direction.

3. The dummy light module of claim 2, wherein the dual SOA light source comprises two SOA units, wherein the first emitting direction of each SOA unit is directed towards a reflector array arranged to redirect the light back to the other SOA unit, and wherein the first light emission and the second light emission are output in the second emitting direction.

4. The dummy light module of claim 2, wherein the first emitting direction of each respective SOA unit is directed towards a corresponding reflector arranged to redirect the light back to the respective SOA unit, and the second emitting direction of each SOA unit is directed towards a power splitter configured to receive the light emitted by each of the SOA units and output the first light emission and the second light emission as identical light emissions.

5. The dummy light module of claim 4, wherein the dual SOA light source comprises at least a first SOA unit configured to emit light in a first band, and a second SOA unit configured to emit light in a second band different than the first band.

6. The dummy light module of claim 5, wherein the dual SOA light source further comprises a first band multiplexer configured to combine the light in the first band and the light in the second band emitted in the first emitting direction, and direct the combined light to a common reflector.

7. The dummy light module of claim 6, wherein the dual SOA light source comprises a wideband SOA unit arranged between the first band multiplexer and the common reflector, wherein the wideband SOA unit comprises the one or more SOA units, and wherein the wideband SOA unit is configured to emit wideband light in the first emitting direction and the second emitting direction, wherein the wideband light includes at least the first band and the second band.

8. The dummy light module of claim 5, wherein the dual SOA light source further comprises:
one or more additional SOA units each configured to emit light in a respective band different from each other band, and
a second band multiplexer configured to combine the light of the different bands emitted in the second emitting direction, and direct the combined light to the power splitter.

9. The dummy light module of claim 3, wherein the light emitted from each SOA unit in the first emitting direction passes through a gain flattening filter (GFF) configured to flatten an emission profile of the dummy light.

10. The dummy light module of claim 9, wherein the GFF is further configured to increase an output power in a frequency band.
